(19) United States
(12) Patent Application Publication
(10) Pub. No.: US 2026/0198046 A1
(43) Pub. Date: Jul. 9, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Fangyuan Kong, Kanazawa Ishikawa (JP); Hiroaki Katou, Nonoichi Ishikawa (JP); Toshifumi Nishiguchi, Hakusan Ishikawa (JP)

(21) Appl. No.: 19/353,029

(22) Filed: Oct. 8, 2025

(30) Foreign Application Priority Data
Jan. 6, 2025 (JP) 2025-001898

(51) Int. Cl. H10D 30/66; H10D 12/00; H10D 62/10; H10D 62/60; H10D 64/00

(52) U.S. Cl. CPC H10D 30/665; H10D 12/415; H10D 12/481; H10D 30/668; H10D 62/102; H10D 62/60; H10D 64/112; H10D 64/117

(57) ABSTRACT

A semiconductor device includes a first electrode, a second electrode, a semiconductor part located between the first electrode and the second electrode, a plurality of third electrodes located inside the semiconductor part in at least an element region, a gate electrode positioned between the plurality of third electrodes, and a wiring layer positioned between the semiconductor part and the second electrode. The wiring layer extends from the element region to a termination region. The wiring layer is connected to the plurality of third electrodes in the element region and connected to the second electrode in the termination region.

### CROSS-REFERENCE TO RELATED APPLICATION

This application is based upon and claims the benefit of priority from Japanese Patent Application No.2025-001898, filed on Jan. 6, 2025; the entire contents of which are incorporated herein by reference.

### FIELD

Embodiments described herein relate generally to a semiconductor device.

### BACKGROUND

In a known semiconductor device, multiple field plate electrodes are arranged in a dot configuration when viewed in plan.

### BRIEF DESCRIPTION OF THE DRAWINGS

FIGS. 1 and 2 are schematic plan views of a semiconductor device according to a first embodiment;

FIG. 3 is an A-A cross-sectional view of FIG. 2;

FIG. 4 is a B-B cross-sectional view of FIG. 2;

FIG. 5 is a C-C cross-sectional view of FIG. 1;

FIG. 6 is a schematic cross-sectional view of a semiconductor device of a second embodiment;

FIG. 7 is a schematic cross-sectional view of a semiconductor device of a third embodiment;

FIGS. 8 and 9 are schematic cross-sectional views of a semiconductor device of a fourth embodiment;

FIG. 10 is a schematic plan view of a semiconductor device of a fifth embodiment; and

FIG. 11 to FIG. 16 are schematic plan views of modified examples of embodiments.

### DETAILED DESCRIPTION

According to one embodiment, a semiconductor device includes an element region; a termination region surrounding the element region; a first electrode; a second electrode; a semiconductor part located between the first electrode and the second electrode; a plurality of third electrodes located inside the semiconductor part in at least the element region; a gate electrode positioned between the plurality of third electrodes; and a wiring layer positioned between the semiconductor part and the second electrode, the wiring layer extending from the element region to the termination region, the wiring layer being connected to the plurality of third electrodes in the element region and connected to the second electrode in the termination region.

Exemplary embodiments will now be described with reference to the drawings. Similar components in the drawings are marked with like reference numerals. In the drawings, a direction along an X-axis is referred to as a first direction X; a direction along a Y-axis is referred to as a second direction Y; and a direction along a Z-axis is referred to as a third direction Z. The first direction X, the second direction Y, and the third direction Z are orthogonal to each other. For example, the arrow direction along the Z-axis is referred to as relatively up or above, and the opposite direction of the arrow along the Z-axis is referred to as relatively down or below.

### First Embodiment

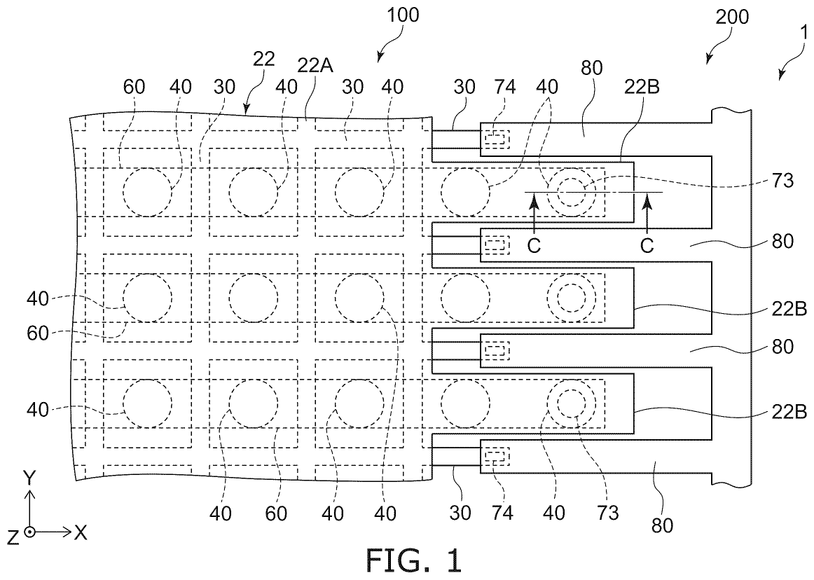

FIG. 1 is a schematic plan view showing an arrangement of major components of a semiconductor device 1 according to a first embodiment.

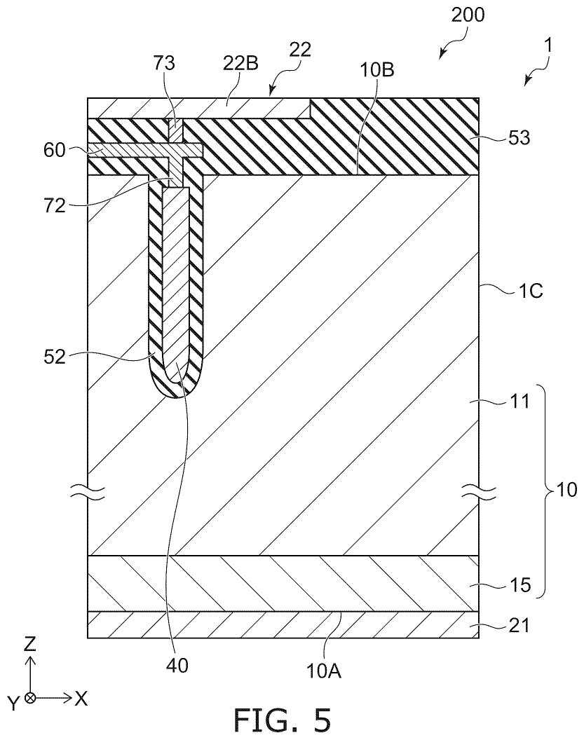

The semiconductor device 1 includes an element region 100 and a termination region 200. For example, the termination region 200 surrounds the element region 100 when viewed in plan. The termination region 200 is positioned between the element region 100 and a side surface 1C of the semiconductor device 1 (shown in FIG. 5) in the first and second directions X and Y.

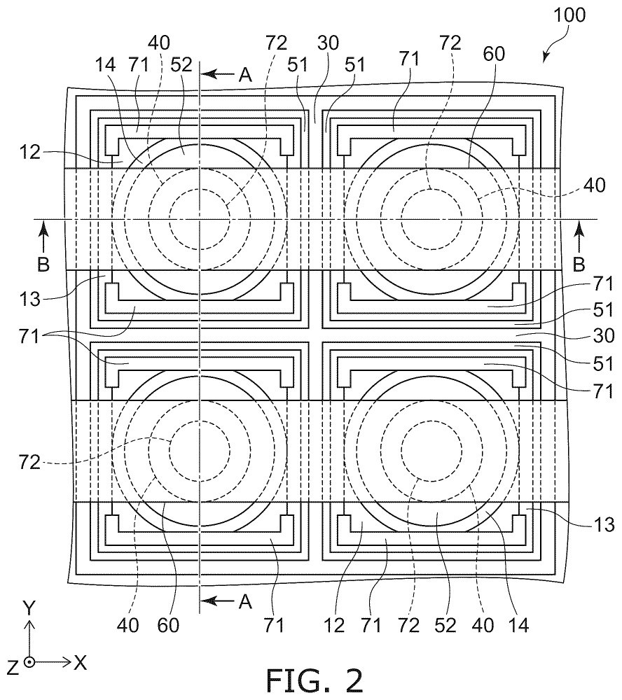

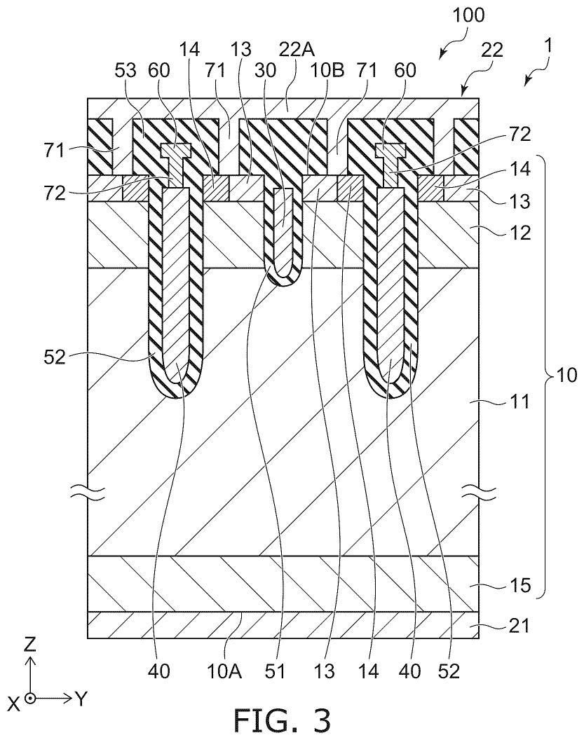

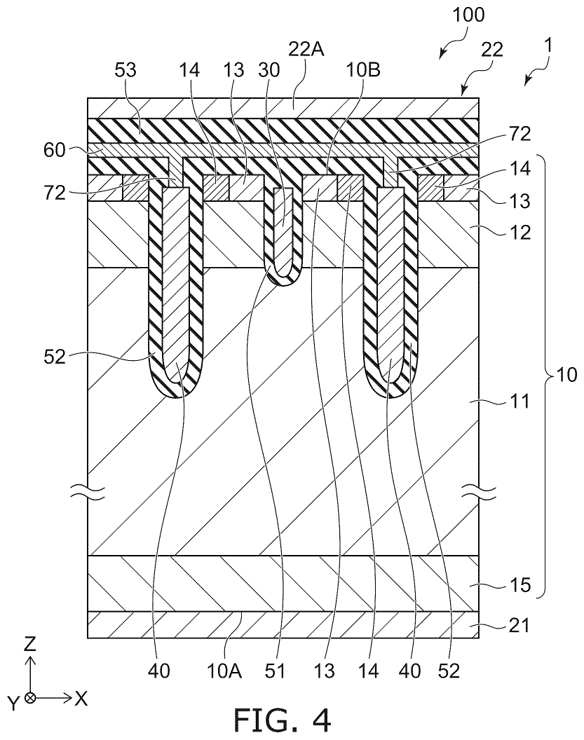

FIG. 2 is a schematic plan view of one part of the element region 100 of the semiconductor device 1. FIG. 3 is an A-A cross-sectional view of FIG. 2. FIG. 4 is a B-B cross-sectional view of FIG. 2.

As shown in FIGS. 3 and 4, the semiconductor device 1 includes a first electrode 21, a second electrode 22, and a semiconductor part 10. The first electrode 21 and the second electrode 22 are separated in the third direction Z. The second electrode 22 is not illustrated in FIG. 2.

The semiconductor part 10 is positioned between the first electrode 21 and the second electrode 22 in the third direction Z. The semiconductor part 10 includes a first surface 10A and a second surface 10B. The first surface 10A faces the first electrode 21 in the third direction Z. The second surface 10B is positioned at the side opposite to the first surface 10A in the third direction Z and faces the second electrode 22.

For example, silicon can be used as the material of the semiconductor part 10. Or, for example, silicon carbide, gallium nitride, etc., may be used as the material of the semiconductor part 10. In the description of the semiconductor part 10 according to the embodiment, a first conductivity type is an n-type, and a second conductivity type is a p-type; however, the first conductivity type may be the p-type; and the second conductivity type may be the n-type.

The semiconductor part 10 includes an n-type first semiconductor layer 11, a p-type second semiconductor layer 12 located on the first semiconductor layer 11, an n-type third semiconductor layer 13 located on the second semiconductor layer 12, and a p-type fourth semiconductor layer 14 located on the second semiconductor layer 12. The n-type impurity concentration of the third semiconductor layer 13 is greater than the n-type impurity concentration of the first semiconductor layer 11. The p-type impurity concentration of the fourth semiconductor layer 14 is greater than the p-type impurity concentration of the second semiconductor layer 12. The semiconductor part 10 also includes a fifth semiconductor layer 15 located between the first electrode 21 and the first semiconductor layer 11.

The semiconductor device 1 according to the embodiment has, for example, a vertical MOSFET (Metal-Oxide-Semiconductor Field Effect Transistor) structure. In the MOSFET, the first electrode 21 functions as a drain electrode; the second electrode 22 functions as a source electrode; the first semiconductor layer 11 functions as a drift layer; the second semiconductor layer 12 functions as a base layer; the third semiconductor layer 13 functions as a source layer; and the fifth semiconductor layer 15 functions as an n-type drain layer that has a higher n-type impurity concentration than the first semiconductor layer 11.

Or, the semiconductor device according to the embodiment may have a vertical IGBT (Insulated Gate Bipolar Transistor) structure. In the IGBT, the first electrode 21 functions as a collector electrode; the second electrode 22 functions as an emitter electrode; the first semiconductor layer 11 functions as a drift layer; the second semiconductor layer 12 functions as a base layer; the third semiconductor layer 13 functions as an emitter layer; and the fifth semiconductor layer 15 functions as a p-type collector layer. In the IGBT, an n-type buffer layer that has a higher n-type impurity concentration than the first semiconductor layer 11 may be located between the fifth semiconductor layer 15 (the collector layer) and the first semiconductor layer 11 (the drift layer).

For example, the fourth semiconductor layer 14 makes it easier for carriers to be discharged to the second electrode 22 at turn-off.

The first electrode 21 contacts the first surface 10A of the semiconductor part 10. According to the embodiment, the first electrode 21 contacts the fifth semiconductor layer 15 and is electrically connected to the fifth semiconductor layer 15.

The second electrode 22 is located on the second surface 10B of the semiconductor part 10 with a third insulating film 53 (described below) interposed.

The semiconductor device 1 according to the embodiment further includes a gate electrode 30 and a first insulating film (gate insulating film) 51. The gate electrode 30 extends downward from the second surface 10B of the semiconductor part 10 and is positioned inside the semiconductor part 10. The lower end of the gate electrode 30 is positioned inside the first semiconductor layer 11 lower than the p-n junction between the second semiconductor layer 12 and the first semiconductor layer 11. For example, conductive polycrystalline silicon can be used as the material of the gate electrode 30.

As shown in FIG. 2, for example, the gate electrode 30 extends in the first and second directions X and Y. As shown in FIG. 3, the second semiconductor layer 12 faces the side surface of the gate electrode 30 in the second direction Y. As shown in FIG. 4, the second semiconductor layer 12 faces the side surface of the gate electrode 30 in the first direction X.

The first insulating film 51 is located between the gate electrode 30 and the semiconductor part 10. The side surface of the gate electrode 30 faces the second semiconductor layer 12 via the first insulating film 51.

The semiconductor device 1 according to the embodiment further includes a third electrode 40 and a second insulating film 52.

The third electrode 40 has a columnar shape extending downward from the second surface 10B of the semiconductor part 10, and is positioned inside the semiconductor part 10. As shown in FIG. 1, the multiple third electrodes 40 are arranged in the first and second directions X and Y when viewed in plan. For example, the multiple third electrodes 40 have a square lattice arrangement in the first and second directions X and Y when viewed in plan. The third electrode 40 is, for example, circular when viewed in plan. The multiple third electrodes 40 are located in at least the element region 100. In the example shown in FIG. 1, the third electrodes 40 also are located in the termination region 200.

As shown in FIGS. 3 and 4, the third electrode 40 does not reach the fifth semiconductor layer 15. The lower end of the third electrode 40 is positioned inside the first semiconductor layer 11. The shortest distance in the third direction Z between the first electrode 21 and the lower end of the third electrode 40 is less than the shortest distance in the third direction Z between the first electrode 21 and the lower end of the gate electrode 30. For example, conductive polycrystalline silicon can be used as the material of the third electrode 40.

The second insulating film 52 is located between the third electrode 40 and the semiconductor part 10.

As shown in FIG. 2, the gate electrode 30 is positioned between the multiple third electrodes 40 when viewed in plan and extends in the first and second directions X and Y.

As shown in FIGS. 3 and 4, the semiconductor device 1 according to the embodiment further includes the third insulating film 53. The third insulating film 53 is located between the second electrode 22 and the second surface 10B of the semiconductor part 10, between the second electrode 22 and the upper surface of the gate electrode 30, and between the third electrode 40 and the second electrode 22.

The semiconductor device 1 according to the embodiment further includes a conductive first connecting part 71. The first connecting part 71 extends through the third insulating film 53 between the second electrode 22 and the second surface 10B of the semiconductor part 10, connects the second electrode 22 and the third semiconductor layer 13, and connects the second electrode 22 and the fourth semiconductor layer 14. For example, the first connecting part 71 contacts the upper surface of the third semiconductor layer 13 and the upper surface of the fourth semiconductor layer 14. The third semiconductor layer 13 and the fourth semiconductor layer 14 are electrically connected to the second electrode 22 via the first connecting part 71. For example, the second electrode 22 and the first connecting part 71 are one monolithic piece made of the same metal material. The second electrode 22 and the first connecting part 71 include, for example, aluminum.

As shown in FIG. 2, for example, one third electrode 40 and two first connecting parts 71 are located in one region surrounded with the gate electrode 30 when viewed in plan. The two first connecting parts 71 are separated from each other in the second direction Y. The one third electrode 40 is positioned between the two first connecting parts 71 that are separated from each other in the second direction Y.

The fourth semiconductor layer 14 continuously surrounds the third electrode 40 in the one region surrounded with the gate electrode 30. The third semiconductor layer 13 continuously surrounds the fourth semiconductor layer 14 in the one region.

The semiconductor device 1 according to the embodiment further includes a wiring layer 60 and a second connecting part 72. As shown in FIG. 4, the wiring layer 60 is positioned between the second electrode 22 and the second surface 10B of the semiconductor part 10 in the third direction Z and extends in the first direction X. The third insulating film 53 is located between the wiring layer 60 and the second surface 10B of the semiconductor part 10 and between the wiring layer 60 and the second electrode 22.

The second connecting part 72 extends through the third insulating film 53 between the wiring layer 60 and the third electrode 40 and connects the wiring layer 60 and the third electrode 40. The second connecting part 72 contacts the upper surface of the third electrode 40. Multiple second connecting parts 72 are located on the third electrodes 40 to correspond to the multiple third electrodes 40. The third electrodes 40 are electrically connected to the wiring layer 60 via the second connecting parts 72. For example, the wiring layer 60 and the second connecting parts 72 are one monolithic piece of the same material. For example, conductive polycrystalline silicon can be used as the material of the wiring layer 60 and the second connecting parts 72.

In the example shown in FIG. 1, the multiple wiring layers 60 are arranged in the second direction Y when viewed in plan; and each wiring layer 60 extends in the first direction X from the element region 100 to the termination region 200. The second electrode 22 includes a major part 22A positioned in the element region 100, and multiple extension parts 22B that extend from the major part 22A into the termination region 200 in the first direction X. When viewed in plan, the major part 22A continuously covers the multiple wiring layers 60 separated from each other in the second direction Y and continuously covers the multiple third electrodes 40 arranged in the first and second directions X and Y. The area of the major part 22A is greater than the area of the extension parts 22B. The major part 22A and the multiple extension parts 22B are one monolithic piece made of the same material. The extension parts 22B are positioned above the wiring layers 60 in the termination region 200. The third electrodes 40 also are located in the termination region 200.

FIG. 5 is a C-C cross-sectional view of FIG. 1.

The semiconductor device 1 according to the embodiment further includes a third connecting part 73 positioned between the wiring layer 60 and the extension part 22B of the second electrode 22 in the termination region 200. The third connecting part 73 extends through the third insulating film 53 between the wiring layer 60 and the extension part 22B of the second electrode 22 and connects the wiring layer 60 and the extension part 22B of the second electrode 22. The third connecting part 73 contacts the upper surface of the wiring layer 60. The third connecting part 73 is conductive and is made of, for example, a metal material.

The third connecting parts 73 are located respectively between the multiple wiring layers 60 extending in the first direction X and the multiple extension parts 22B of the second electrode 22 extending in the first direction X. Each wiring layer 60 is electrically connected to the second electrode 22 via the third connecting part 73 in the termination region 200. Each of the multiple third electrodes 40 is electrically connected to the second electrode 22 via the second connecting part 72, the wiring layer 60, and the third connecting part 73.

In the element region 100 as described above, the semiconductor part 10 includes the first semiconductor layer 11, the second semiconductor layer 12, the third semiconductor layer 13, the fourth semiconductor layer 14, and the fifth semiconductor layer 15. In the termination region 200, the semiconductor part 10 includes the first semiconductor layer 11 and the fifth semiconductor layer 15. The third semiconductor layer 13 (the source layer or the emitter layer) that is connected to the second electrode 22 and forms a portion of the major current path in the vertical direction is not located on the first semiconductor layer 11 in the termination region 200. In the termination region 200, the second semiconductor layer 12 and the third semiconductor layer 13 may or may not be located on the first semiconductor layer 11. A p-type layer that is different from the second and third semiconductor layers 12 and 13 may be located on the first semiconductor layer 11 in the termination region 200.

As shown in FIG. 1, multiple gate wiring parts 80 that extend in the first direction X are located in the termination region 200. The gate wiring parts 80 are separated from the second electrode 22 on the third insulating film 53. The gate wiring parts 80 that extend in the first direction X are connected to each other and connected to a gate pad (not illustrated). For example, the gate wiring part 80 and the extension part 22B of the second electrode 22 are alternately arranged in the second direction Y.

For example, a portion of the gate electrode 30 having the mesh pattern extending in the first and second directions X and Y in the element region 100 extends in the first direction X from the element region 100 to the termination region 200. In the termination region 200, the gate electrode 30 extends in the first direction X so that the gate electrode 30 overlaps the gate wiring part 80 from below, and is electrically connected to the gate wiring part 80 via a conductive fourth connecting part 74.

When a first potential (e.g., a positive potential) is applied to the first electrode 21 and a second potential (e.g., a ground potential) that is lower than the first potential is applied to the second electrode 22 and a gate voltage that is not less than a threshold is applied to the gate electrode 30, an n-type channel is formed in a region of the second semiconductor layer 12 facing the side surface of the gate electrode 30. A current flows between the first electrode 21 and the second electrode 22 via the fifth semiconductor layer 15, the first semiconductor layer 11, the channel, and the third semiconductor layer 13; and the semiconductor device 1 is set to an on-state.

In an off-state of the semiconductor device 1 in which the application to the gate electrode 30 of the voltage that is not less than the threshold is stopped, a depletion layer spreads from the p-n junction between the second semiconductor layer 12 and the first semiconductor layer 11 and from the boundary between the second insulating film 52 and the first semiconductor layer 11; and the breakdown voltage of the semiconductor device 1 is maintained.

The third electrodes 40 that are electrically connected to the second electrode 22 are field plate electrodes to relax the electric field distribution of the first semiconductor layer 11 (the drift layer) in the off-state of the semiconductor device 1 and increase the breakdown voltage of the semiconductor device 1.

According to the embodiment, compared to a configuration in which the multiple third electrodes 40 and the multiple gate electrodes 30 have a stripe pattern, the channel can be larger and the on-resistance can be reduced by using a configuration in which the multiple third electrodes 40 (the field plate electrodes) are arranged in a dot configuration and the gate electrode 30 has a mesh pattern surrounding the third electrodes 40.

As a comparative example, a configuration may be considered in which the multiple third electrodes 40 that are arranged in a dot configuration are connected to the second electrode 22 directly above the third electrodes 40 without going through the wiring layer 60. In the configuration of such a comparative example, the resistances of the third electrodes 40 are less than those of the embodiment in which the wiring layer 60 is interposed. Therefore, there is a risk that the resistance of a snubber circuit also may be low, and noise (current ringing) may be increased.

The snubber circuit is connected in parallel to the first and second electrodes 21 and 22 of the semiconductor device 1, and is a circuit that absorbs transient high voltages generated at turn-off of the semiconductor device 1. For example, an RC circuit that includes a resistance and a capacitor connected in series can be used as the snubber circuit. The snubber circuit is electrically connected to the third electrodes 40 via the second electrode 22.

According to the embodiment, the multiple third electrodes 40 that are located in the element region 100 are connected respectively to the wiring layers 60 in the element region 100; and the wiring layers 60 extend from the element region 100 to the termination region 200 to be connected to the second electrode 22 in the termination region 200. As a result, compared to the comparative example, the resistances of the third electrodes 40 can be increased, the resistance of the snubber circuit also can be increased, and the noise can be reduced.

It is favorable for the resistivity of the wiring layer 60 to be greater than the resistivity of the second electrode 22. It is favorable for the resistivity of the wiring layer 60 to be not less than the resistivity of the third electrode 40.

The wiring layers 60 extend from the element region 100 to the termination region 200 and are connected to the second electrode 22 in the termination region 200. The wiring layers 60 are not connected to the second electrode 22 in the element region 100. As a result, the layout of the members of the element region 100 is not affected. It is easy to increase resistances of the third electrodes 40 by connecting the wiring layers 60 to the second electrode 22 only in the termination region 200. It is noted that the wiring layers 60 also may be connected to the second electrode 22 in the element region 100.

Although the third semiconductor layer 13 (the source layer or the emitter layer) that is positioned directly under the wiring layer 60 cannot be connected to the second electrode 22 positioned above the wiring layer 60 due to obstruction by the wiring layer 60, the on-resistance can be reduced by further providing the third semiconductor layer 13 directly under the wiring layer 60 as shown in FIGS. 2 and 4.

Other embodiments will now be described. According to the other embodiments, components that are different from those of the first embodiment above are mainly described. According to the other embodiments as well, similarly to the first embodiment above, the noise can be reduced.

### Second Embodiment

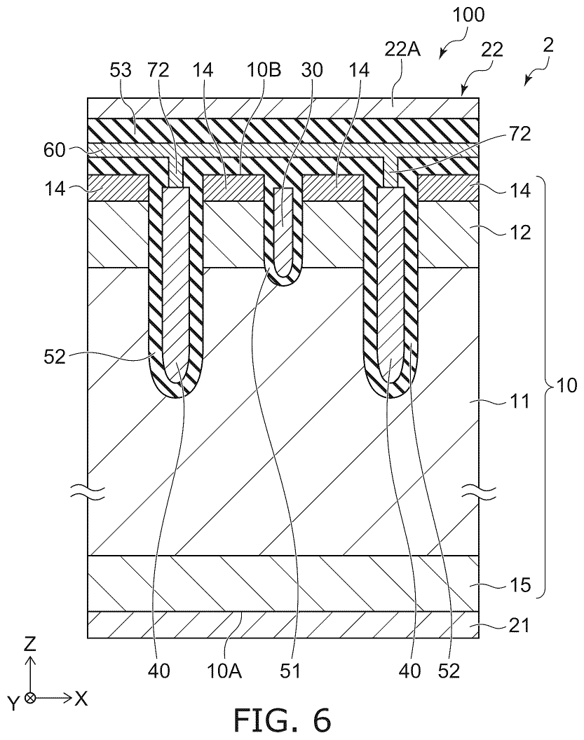

FIG. 6 is a cross section (an XZ cross section) parallel to the first direction X in which the wiring layer 60 extends, in which the wiring layer 60 of the element region 100 of a semiconductor device 2 according to a second embodiment is positioned. In the semiconductor device 2 according to the second embodiment, the cross section (the YZ cross section) of the element region 100 parallel to the second direction Y is the same as that of FIG. 3.

According to the second embodiment, the third semiconductor layer 13 is not located directly under the wiring layer 60. Only the fourth semiconductor layer 14 is located on the second semiconductor layer 12 directly under the wiring layer 60 in the element region 100.

When the third semiconductor layer 13 that is not connected to the second electrode 22 is positioned directly under the wiring layer 60, there is a risk that the avalanche resistance may be reduced by the operation of a parasitic n-p-n transistor. According to the second embodiment, the third semiconductor layer 13 is not positioned directly under the wiring layer 60, and so a reduction of the avalanche resistance can be suppressed.

### Third Embodiment

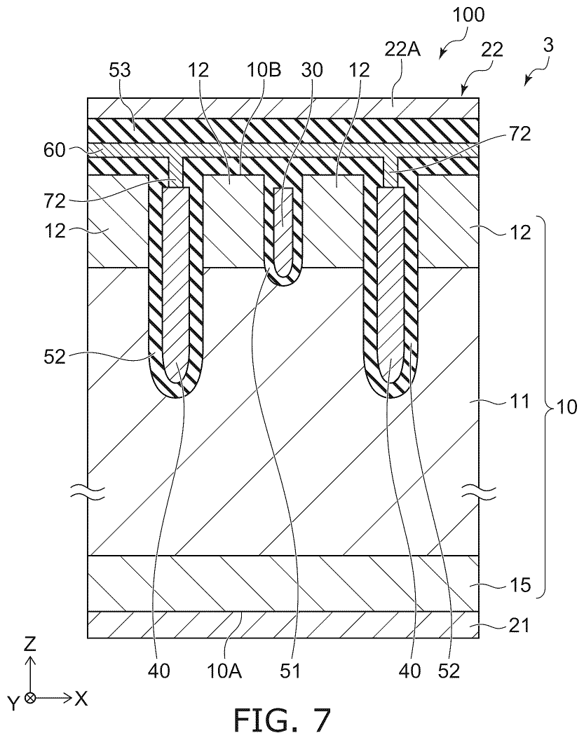

FIG. 7 is a cross section (an XZ cross section) parallel to the first direction X in which the wiring layer 60 extends, in which the wiring layer 60 of the element region 100 of a semiconductor device 3 according to a third embodiment is positioned.

As in the semiconductor device 3 according to the third embodiment, the third semiconductor layer 13 and the fourth semiconductor layer 14 may not be located on the second semiconductor layer 12 directly under the wiring layer 60 in the element region 100. As a result, a reduction of the avalanche resistance can be suppressed.

### Fourth Embodiment

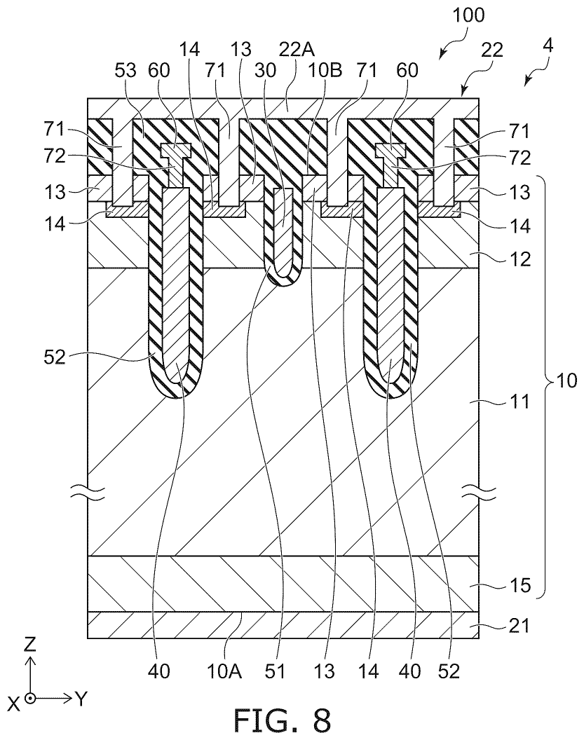

FIG. 8 is a cross section (a YZ cross section) parallel to the second direction Y of the element region 100 of a semiconductor device 4 according to a fourth embodiment.

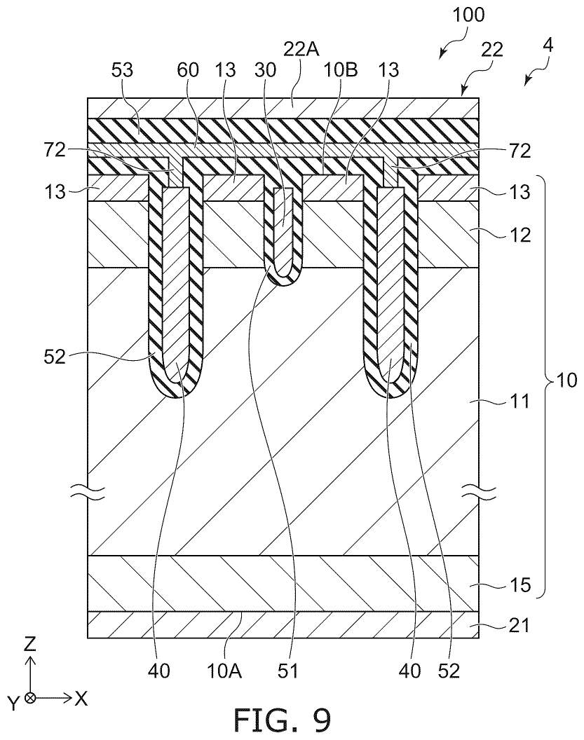

FIG. 9 is a cross section (an XZ cross section) parallel to the first direction X in which the wiring layer 60 extends, in which the wiring layer 60 of the element region 100 of the semiconductor device 4 according to the fourth embodiment is positioned.

As shown in FIG. 8, the fourth semiconductor layer 14 is located between the second semiconductor layer 12 and the third semiconductor layer 13. The first connecting part 71 that extends downward from the second electrode 22 extends through the third semiconductor layer 13 and reaches the fourth semiconductor layer 14. The first connecting part 71 contacts the side surface of the third semiconductor layer 13. In such a configuration, compared to a configuration in which the first connecting part 71 contacts only the upper surface of the third semiconductor layer 13, the contact resistance between the first connecting part 71 and the third semiconductor layer 13 is reduced, and the on-resistance is easily reduced.

As shown in FIG. 9, the fourth semiconductor layer 14 is not located directly under the wiring layer 60. Only the third semiconductor layer 13 is located on the second semiconductor layer 12 directly under the wiring layer 60 in the element region 100. According to the fourth embodiment, as in the third embodiment shown in FIG. 7, neither the third semiconductor layer 13 nor the fourth semiconductor layer 14 may be located on the second semiconductor layer 12 directly under the wiring layer 60 in the element region 100.

### Fifth Embodiment

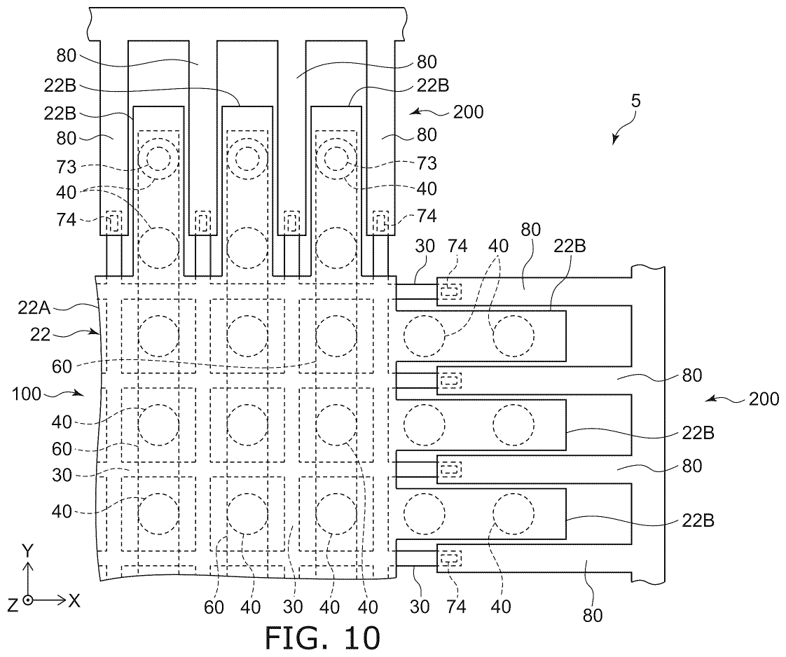

FIG. 10 is a schematic plan view showing an arrangement of major components of a semiconductor device 5 according to a fifth embodiment.

In the semiconductor device 5 according to the fifth embodiment, the multiple wiring layers 60 are arranged in the first direction X when viewed in plan; and each wiring layer 60 extends in the second direction Y from the element region 100 to the termination region 200. The multiple extension parts 22B of the second electrode 22 extend in the second direction Y from the major part 22A located in the element region 100 to the termination region 200. The third connecting parts 73 are located respectively between the multiple wiring layers 60 extending in the second direction Y and the multiple extension parts 22B extending in the second direction Y. Each wiring layer 60 is electrically connected to the second electrode 22 via the third connecting part 73 in the termination region 200 that is positioned further outward in the second direction Y than the element region 100.

The third electrode 40 that is located in the termination region 200, which is positioned further outward in the first direction X than the element region 100, can be connected directly to the extension part 22B of the second electrode 22 without going through the wiring layer 60.

In the semiconductor device 5 according to the fifth embodiment, the multiple gate wiring parts 80 that extend in the second direction Y are located in the termination region 200 that is positioned further outward in the second direction Y than the element region 100. The gate wiring parts 80 that extend in the second direction Y are connected to each other and connected to a gate pad (not illustrated).

The gate electrode 30 extends in the second direction Y from the element region 100 to the termination region 200. The gate electrode 30 in the termination region 200 extends in the second direction Y so that the gate electrode 30 overlaps the gate wiring part 80 from below, and is electrically connected to the gate wiring part 80 via the fourth connecting part 74.

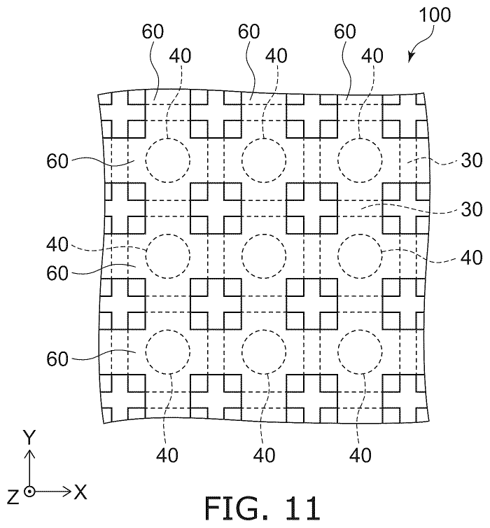

In the element region 100 as shown in FIG. 11, the multiple wiring layers 60 may have a mesh pattern extending in the first and second directions X and Y. The wiring layers 60 are connected to the extension part 22B of the second electrode 22 via the third connecting part 73 in the termination region 200 in the first direction X and in the termination region 200 in the second direction Y.

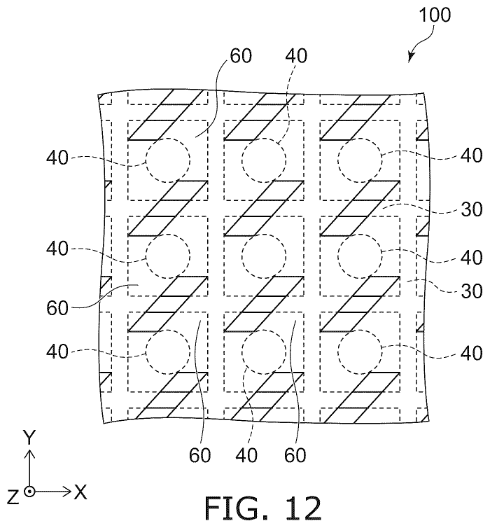

In the element region 100 as shown in FIG. 12, a pattern may be used in which the multiple wiring layers 60 extend in the first direction X, and the wiring layers 60 that extend in the first direction X are connected to each other by wiring layers 60 that extend in a direction that is oblique to the first and second directions X and Y.

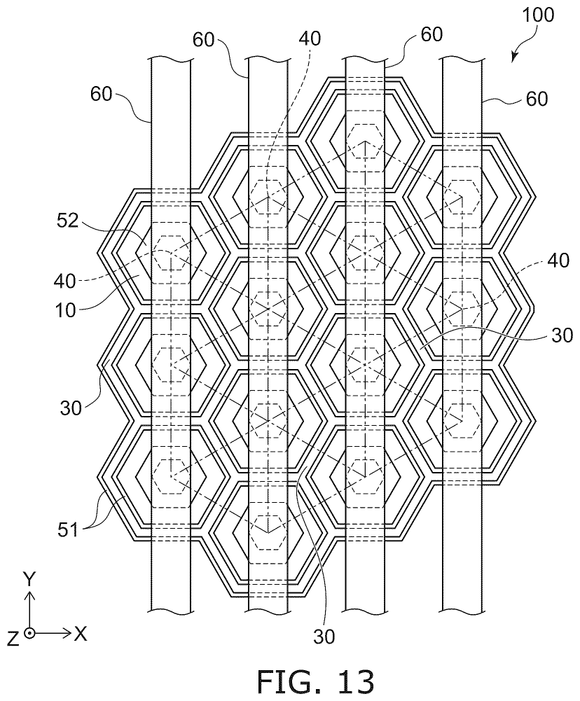

As shown in FIG. 13, double dot-dash lines virtually illustrate multiple triangles (in the example, equilateral triangles) arranged to gaplessly contact each other when viewed in plan. The multiple third electrodes 40 may be positioned respectively at the vertices of the triangles. As a result, the gate electrode 30 can have a honeycomb mesh pattern between the multiple third electrodes 40 arranged with maximum packing. Such a configuration can have a lower on-resistance than a configuration in which the gate electrode 30 that has a lattice mesh pattern is located between the multiple third electrodes 40 having a square lattice arrangement.

When viewed in plan, the gate electrode 30 is positioned between the multiple third electrodes 40 and has a hexagonal (in the example, a regular hexagonal) pattern surrounding one third electrode 40. The planar pattern of the gate electrode 30 is a honeycomb mesh pattern in which multiple hexagonal patterns are repeated.

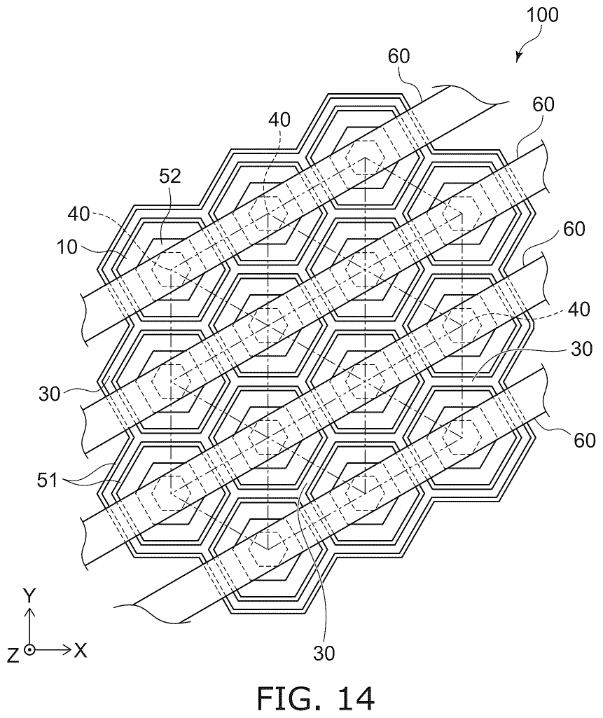

In the example shown in FIG. 13, the wiring layers 60 extend in the second direction Y over the multiple third electrodes 40 arranged in the second direction Y. As shown in FIG. 14, the wiring layers 60 may extend in a direction that is oblique to the first and second directions X and Y.

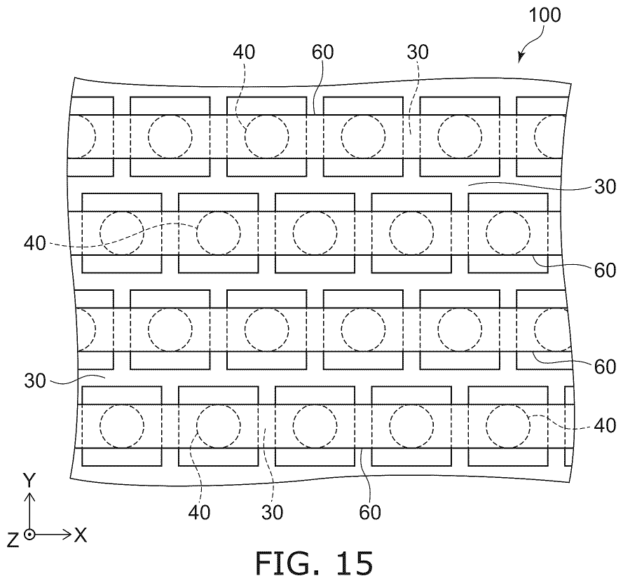

As shown in FIG. 15, the multiple third electrodes 40 may be arranged to zigzag in the second direction Y when viewed in plan. The positions in the first direction X of the centers of the third electrodes 40 adjacent to each other in the second direction Y are shifted from each other in the first direction X.

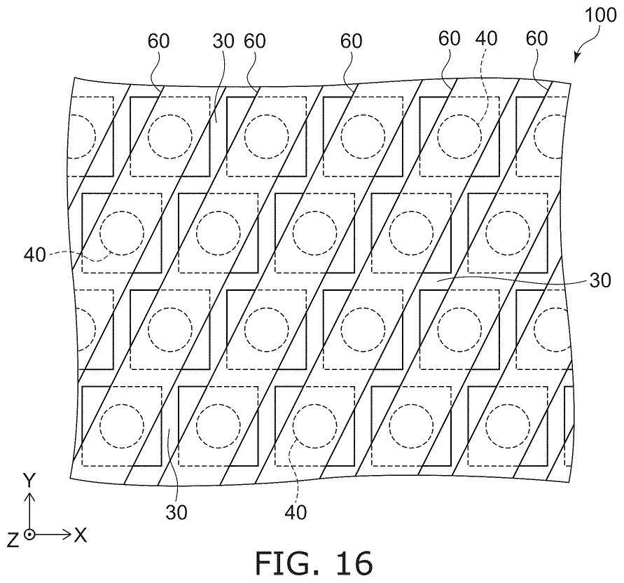

In the example shown in FIG. 15, the wiring layers 60 extend in the first direction X over the multiple third electrodes 40 arranged in the first direction X. As shown in FIG. 16, the wiring layers 60 may extend in a direction that is oblique to the first and second directions X and Y.

The positions in the second direction Y of the centers of the third electrodes 40 adjacent to each other in the first direction X may be shifted from each other in the second direction Y.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
an element region;
a termination region surrounding the element region;
a first electrode;
a second electrode;
a semiconductor part located between the first electrode and the second electrode;
a plurality of third electrodes located inside the semiconductor part in at least the element region;
a gate electrode positioned between the plurality of third electrodes; and
a wiring layer positioned between the semiconductor part and the second electrode, the wiring layer extending from the element region to the termination region, the wiring layer being connected to the plurality of third electrodes in the element region and connected to the second electrode in the termination region.

2. The device according to claim 1, wherein
a resistivity of the wiring layer is greater than a resistivity of the second electrode.

3. The device according to claim 1, wherein
a resistivity of the wiring layer is not less than a resistivity of the third electrode.

4. The device according to claim 1, wherein
the semiconductor part includes:
a first semiconductor layer located on the first electrode, the first semiconductor layer being of a first conductivity type;
a second semiconductor layer located on the first semiconductor layer, the second semiconductor layer facing the gate electrode, the second semiconductor layer being of a second conductivity type; and
a third semiconductor layer located on the second semiconductor layer and connected to the second electrode, the first conductivity type having a higher first-conductivity-type impurity concentration than the first semiconductor layer.

5. The device according to claim 4, wherein
the third semiconductor layer is not located directly under the wiring layer.

6. The device according to claim 4, wherein
the semiconductor part further includes a fourth semiconductor layer located on the second semiconductor layer and connected to the second electrode, and
the fourth semiconductor layer is of the second conductivity type and has a higher second-conductivity-type impurity concentration than the second semiconductor layer.

7. The device according to claim 6, wherein
the fourth semiconductor layer is not located directly under the wiring layer.

8. The device according to claim 6, wherein
the third semiconductor layer and the fourth semiconductor layer are not located directly under the wiring layer.

9. The device according to claim 1, wherein
each of the plurality of third electrodes is columnar.

10. The device according to claim 1, wherein
the plurality of third electrodes are arranged in a first direction and a second direction, and
the second direction is orthogonal to the first direction.

11. The device according to claim 10, wherein
a plurality of the wiring layers extend in the first and second directions.

12. The device according to claim 10, wherein
the gate electrode extends in the first and second directions.

13. The device according to claim 12, wherein
the gate electrode surrounds one region by extending in the first and second directions, and
one of the plurality of third electrodes is located in the one region.

14. The device according to claim 1, wherein
the gate electrode has a hexagonal pattern surrounding one of the plurality of third electrodes.

15. The device according to claim 4, wherein
the semiconductor part further includes a fifth semiconductor layer located between the first electrode and the first semiconductor layer.

16. The device according to claim 15, wherein
the fifth semiconductor layer is of the first conductivity type, and
the fifth semiconductor layer has a higher first-conductivity-type impurity concentration than the first semiconductor layer.

17. The device according to claim 15, wherein
the fifth semiconductor layer is of the second conductivity type.

18. The device according to claim 6, wherein
the plurality of third electrodes are arranged in a first direction and a second direction,
the second direction is orthogonal to the first direction,
the gate electrode extends in the first and second directions,
the gate electrode surrounds one region by extending in the first and second directions,
the fourth semiconductor layer continuously surrounds one of the plurality of third electrodes in the one region, and
the third semiconductor layer continuously surrounds the fourth semiconductor layer in the one region.

19. The device according to claim 1, wherein
the wiring layer is not connected to the second electrode in the element region.

20. The device according to claim 1, wherein
the wiring layer is made of silicon.
